(19) United States
(12) Patent Application Publication
(10) Pub. No.: US 2006/0289940 A1
(43) Pub. Date: Dec. 28, 2006

(54) Fin FET CMOS device, method of manufacturing the same, and memory including fin FET CMOS device

(76) Inventors: Jae-Woong Hyun, Uijeongbu-si (KR); Yoon-Dong Park, Yongin-si (KR); Won-joo Kim, Suwon-si (KR); Sung-jae Byun, Seognam-si (KR)

Correspondence Address: HARNESS, DICKEY & PIERCE, P.L.C., P.O. BOX 8910, RESTON, VA, 20195, US

(21) Appl. No.: 11/475,912

(22) Filed: Jun. 28, 2006

(30) Foreign Application Priority Data
Jun. 28, 2005 (KR) 10-2005-0056226

(51) Int. Cl. H01L 29/94

(52) U.S. Cl. 257/369

(57) ABSTRACT

A fin FET CMOS device, a method of manufacturing the same, and a memory including the fin FET CMOS device are provided. The CMOS device may include a substrate, an n-type transistor disposed on the substrate, an interlayer insulating layer disposed on the n-type transistor, and a p-type transistor disposed on the interlayer insulating layer. The n-type transistor and the p-type transistor may have a common gate insulating layer and a fin gate.

### PRIORITY STATEMENT

This application claims the benefit of Korean Patent Application No. 10-2005-0056226, filed on Jun. 28, 2005, in the Korean Intellectual Property Office, the disclosure of which is incorporated herein in its entirety by reference.

### BACKGROUND OF THE INVENTION

1. Field of the Invention

Example embodiments of the present invention relate to a CMOS device, a method of manufacturing the same, and a memory including the CMOS device, for example, to a fin FET CMOS device, a method of manufacturing the same, and a memory including the fin FET CMOS device.

2. Description of the Related Art

With the development of industrial technology, a variety of smaller electronic products with many functions have been introduced. These electronic products may include semiconductor devices suitable for the functions. Examples of such semiconductor devices may include transistors, memories, and/or logic devices.

As Internet technologies are rapidly developed and a variety of electronic products accessible to the Internet are available, an amount of usable information that is available to users is rapidly increasing. Smaller electronic products that are capable of store more data and quickly process data are in great demand. Accordingly, developments of semiconductor devices that can be used in these electronic products are increasing.

Areas of improvement for semiconductor devices may include increasing the degree of integration and/or operation speed, and/or the reduction of power consumption. If the semiconductor device is a semiconductor memory device, areas of improvement may further include reducing data volatility and improving recording and/or erasing operations.

A variety of semiconductor devices and electronic products have been introduced.

A CMOS device is a device that may resolve one or more drawbacks of transistors, including P-type transistors and N-type transistors. A CMOS device may be manufactured using a conventional semiconductor manufacturing process and may have lower power consumption. An operating speed of a CMOS device is about the same as the operating speeds of an N-type transistor and a P-type transistor.

Because of these characteristics, CMOS devices are widely used in semiconductor devices. For example, an SRAM may include two pull-up transistors, two pull-down transistors, and two pass transistors. In such an SRAM, one pull-up transistor and one pull-down transistor may have the CMOS structure.

A conventional CMOS device may include a P-type transistor and an N-type transistor, which are formed at different locations of a single base substrate. That is, the P-type transistor may be formed beside the N-type transistor. Accordingly, compared with the case where one of the N-type transistor and the P-type transistor is formed on the base substrate, the CMOS device occupies a larger area of the base substrate.

An SRAM may operate at higher speed and reduced power consumption. However, because the CMOS device may occupy a larger area on the base substrate, there may be a limitation in increasing the degree of integration.

### SUMMARY OF THE INVENTION

Example embodiments of the present invention provide a fin FET CMOS device capable of increasing the degree of integration.

Example embodiments of the present invention also provide a method of manufacturing the fin FET CMOS device.

Example embodiments of the present invention further provide a memory including a fin FET CMOS device.

According to an example embodiment of the present invention, there is provided a CMOS device including: a substrate; an n-type transistor disposed on the substrate; an interlayer insulating layer disposed on the n-type transistor; and a p-type transistor disposed on the interlayer insulating layer, wherein the n-type transistor and the p-type transistor have a common gate insulating layer and a fin gate.

In an example embodiment, a source of the n-type transistor and a drain of the p-type transistor may be connected to a conductive plug, the source of the n-type transistor being grounded. A contact hole exposing the source of the n-type transistor may be formed in a stack structure including the interlayer insulating layer and a source of the p-type transistor, an inner side surface of the contact hole may be covered with a spacer, and the contact hole inside the spacer may be filled with a conductive plug.

In an example embodiment, the sources and the drains of the n-type and p-type transistors may have an LDD (lightly doped drain) structure.

In an example embodiment, the doping concentration of the source and the drain of the p-type transistor may be higher than the doping concentration of the source and the drain of the n-type transistor by at least one order of magnitude.

In an example embodiment, the spacer may be formed of a nitride layer.

In an example embodiment, the n-type transistor may be formed on a first semiconductor layer with a (100) crystal face.

In an example embodiment, the p-type transistor may be formed on a second semiconductor layer with a (110) crystal face.

In an example embodiment, the substrate may be a silicon on insulator (SOI) substrate.

According to another example embodiment of the present invention, there is provided a method of manufacturing a CMOS device, including: sequentially stacking a first semiconductor layer, an interlayer insulating layer, and a second semiconductor layer; forming a mask in a portion of the second semiconductor layer; sequentially etching an exposed portion of the second semiconductor layer, and the interlayer insulating layer and the first semiconductor layer disposed under the exposed portion; removing the mask; sequentially forming a gate insulating layer and a gate with a fin part, the gate insulating layer entirely covering the exposed portion of the second semiconductor layer, the interlayer insulating layer, and the first semiconductor layer; forming first and second n− doping regions on the first semiconductor layer and spaced apart from each other by the fin part; forming first and second p− doping regions on the second semiconductor layer and spaced apart from each other by the fin part; forming a gate spacer on a side surface of the fin part; forming first and second n+ doping regions in the first and second n− doping regions using the gate spacer as a mask, respectively; and forming first and second p+ doping regions in the first and second p− doping regions using the gate spacer as a mask.

In an example embodiment, the first semiconductor layer may be formed of a silicon layer with a (100) crystal face. The second semiconductor layer may be formed of a silicon layer with a (110) crystal face.

In an example embodiment, the fin gate may be formed using a lift-off method.

In an example embodiment, the first and second n+ doping regions may be formed by obliquely doping n-type conductive impurity ions at a predetermined angle. The predetermined angle may be 30°.

In an example embodiment, doping concentration of the first and second p− doping regions may be higher than that of the first and second n− doping regions by at least one order of magnitude. Doping concentration of the first and second p+doping regions may be higher than that of the first and second n+ doping regions by at least one order of magnitude.

In an example embodiment, the method may further include: forming a second interlayer insulating layer on the substrate to cover the second semiconductor layer, the interlayer insulating layer, the first semiconductor layer, the fin gate, and the gate spacer; forming a contact hole exposing the second n+ doping region in a stack structure, the stack structure including the second interlayer insulating layer, the second semiconductor layer, and the interlayer insulating layer; filling the contact hole with a conductive plug; forming a contact hole exposing the first p− doping region and a contact hole exposing the gate in the second interlayer insulating layer; filling the contact hole exposing the first p− doping region and the gate with a conductive plug; forming a contact hole exposing the first n+ doping region in a stack structure, the stack structure including the second interlayer insulating layer, the second semiconductor layer, and the interlayer insulating layer; forming a spacer to cover an inner surface of the contact hole exposing the first n+ doping region; and filling the contact hole inside the spacer with a conductive plug.

In an example embodiment, the method may further include: forming a second interlayer insulating layer on the substrate to cover the second semiconductor layer, the interlayer insulating layer, the first semiconductor layer, the fin gate, and the gate spacer; forming a first contact hole exposing the second n+ doping region and a second contact hole exposing the first n+ doping region in a stack structure, the stack structure including the second interlayer insulating layer, the second semiconductor layer, and the interlayer insulating layer; filling the first contact hole with a conductive plug in a state in which the second contact hole is masked; forming a spacer to cover an inner surface of the second contact hole in a state in which the second contact hole is unmasked; filling the second contact hole inside the spacer with a conductive plug; forming a contact hole exposing the first p+ doping region and a contact hole exposing the gate in the secondy interlayer insulating layer; and filling the contact hole exposing the first p− doping region and the contact hole exposing the gate with a conductive plug.

In an example embodiment, the spacer may be formed of a nitride layer.

According to another example embodiment of the present invention, there is provided a memory device, for example, an SRAM including: at least one p-type pull-up transistor and at least one n-type pull-down transistor sequentially stacked, with an interlayer insulating layer being interposed therebetween, the p-type pull-up transistor and the n-type pull-down transistor including a common gate insulating layer and a fin gate.

In an example embodiment, the n-type pull-down transistor may be formed of a silicon layer with a (100) crystal face. The p-type pull-up transistor may be formed of a silicon layer with a (110) crystal face.

In an example embodiment, doping concentration of source and drain of the p-type pull-up transistor may be higher than doping concentration of source and drain of the n-type pull-down transistor by at least one order of magnitude.

In an example embodiment, a drain region of the p-type pull-up transistor and a drain region of the n-type pull-down transistor may be connected together through a conductive plug.

In an example embodiment, a contact hole exposing the source of the n-type pull-down transistor may be formed in a stack structure including a source region of the p-type pull-up transistor and the interlayer insulating layer, an inner surface of the contact hole may be covered with a spacer, and the contact hole inside the spacer may be filled with a conductive plug. In an example embodiment, the spacer may be formed of a nitride layer.

In an example embodiment, a second interlayer insulating layer may be disposed on the p-type pull-up transistor, a contact hole exposing a source region of the p-type pull-up transistor and a contact exposing the fin gate may be formed in the second interlayer insulating layer, and the contact holes may be filled with a conductive plug.

According to example embodiments of the present invention, a CMOS device and a semiconductor memory with improved integration may be obtained.

### BRIEF DESCRIPTION OF THE DRAWINGS

The above and other features and advantages of the present invention will become more apparent by describing in detail exemplary embodiments thereof with reference to the attached drawings in which:

FIG. 1 is a perspective view of a fin FET CMOS device according to an example embodiment of the present invention;

FIGS. 2 through 4 are example plan views of the fin FET CMOS device illustrated in FIG. 1, in which cutting lines are drawn in different directions;

FIG. 5 is an example sectional view taken along line 5-5′ in FIG. 2;

FIG. 6 is an example sectional view taken along line 6-6′ in FIG. 3;

FIG. 7 is an example sectional view taken along line 7-7′ in FIG. 4;

FIG. 8 is an example sectional view taken along line 8-8′ in any one of FIGS. 2 through 4;

FIGS. 9 through 12 are example perspective views illustrating an example method of manufacturing the CMOS device of FIG. 1;

FIGS. 13 through 25 are example sectional views illustrating an example method of manufacturing the CMOS device of FIG. 1; and

FIG. 26 is an example circuit diagram of an SRAM including the fin FET CMOS device illustrated in FIG. 1.

### DETAILED DESCRIPTION OF EXAMPLE EMBODIMENTS THE INVENTION

Hereinafter, a fin FET CMOS device, a method of manufacturing the same, and a memory including a fin FET CMOS device will be described in detail with reference to the accompanying drawings. In the drawings, the thicknesses of layers and regions are exaggerated for clarity.

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the sizes and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on”, “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

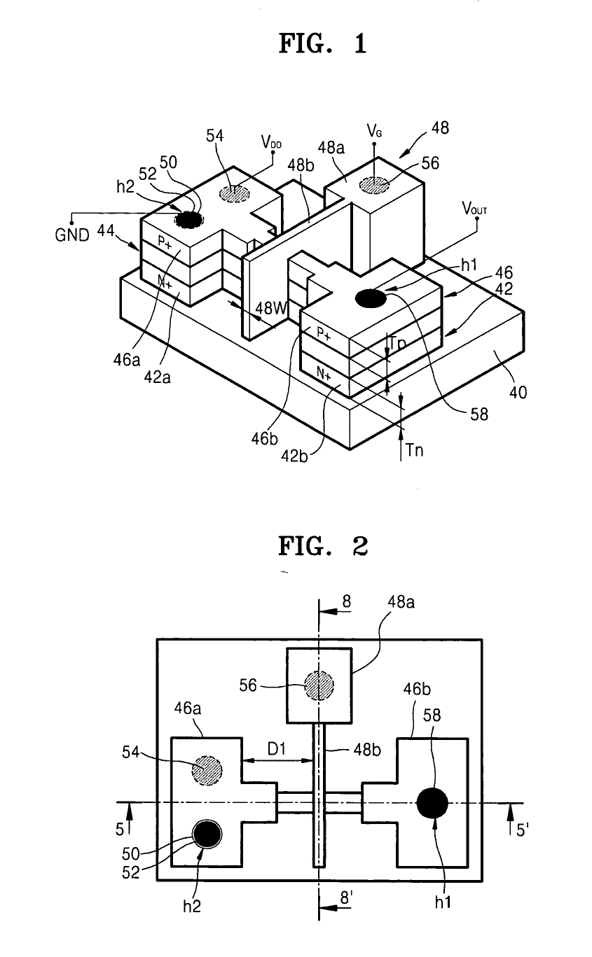

A fin FET CMOS device according to an example embodiment of the present invention (hereinafter, referred to as the fin FET CMOS of an example embodiment the present invention) will now be described. FIG. 1 is a perspective view of a fin FET CMOS device according to an example embodiment of the present invention.

Referring to FIG. 1, a buffer layer 40 may be disposed on a semiconductor substrate (not shown). The buffer layer 40 may be a silicon oxide layer (SiO₂). A first semiconductor layer 42 may be disposed on the buffer layer 40. The first semiconductor layer 42 may be a silicon layer with a (100) crystal face. The first semiconductor layer 42 may have a thickness Tn of 50 nm. The thickness Tn of the first semiconductor layer 42 may be different depending on its constituent material. The first semiconductor layer 42 may include first and second impurity regions 42a and 42b and a first channel region (not shown). The first and second impurity regions 42a and 42b may be doped with n-type conductive impurities. One of the first and second impurity regions 42a and 42b is a source region and the other is a drain region. The first channel region is disposed between the first impurity region 42a and the second impurity region 42b. A portion or all of the sides of the first channel region may be covered with a fin part 48b of a gate 48. The fin part 48b of the gate 48 may have a thickness 48W of about 30 nm. A width of the first semiconductor layer 42 may be narrower from the first and second impurity regions 42a and 42b toward the first channel region.

An interlayer insulating layer 44 may be disposed on the first semiconductor layer 42, for example, in the same shape as the first semiconductor layer 42. The interlayer insulating layer 44 may be a silicon oxide layer. A portion or all of the sides of the interlayer insulating layer 44 formed on the first channel region may also be covered with the fin part 48b of the gate 48. A second semiconductor layer 46 may be disposed on the interlayer insulating layer 44, for example, in the same shape as the first semiconductor layer 42. The second semiconductor layer 46 may be a silicon layer with a (110) crystal face. The second semiconductor layer 46 may have a thickness Tp of about 50 nm. The thickness Tp of the second semiconductor layer 46 may be different depending on its constituent material. The second semiconductor layer 46 may include third and fourth impurity regions 46a and 46b and a second channel region (not shown). The second channel region may be disposed on the first channel region of the first semiconductor layer 42. An exposed entire surface (side and/or top surfaces) of the first semiconductor layer 42 may be covered with the fin part 48b of the gate 48.

The third and fourth impurity regions 46a and 46b may be doped with p-type conductive impurities. One of the third and fourth impurity regions 46a and 46b is a source region and the other is a drain region. Like the first semiconductor layer 42, a width of the second semiconductor layer 46 may be narrower from the third and fourth impurity regions 46a and 46b toward the second channel region.

The fin part 48b of the gate 48 may be formed in a vertical direction with respect to the first and second channel regions. The fin part 48b may contact the side surfaces of the first channel region and the sides and top surfaces of the second channel region. The fin part 48b may extend from a contact region 48a of the gate 48 in a fin shape. The contact region 48a of the gate may be wider than the fin part 48b in a vertical direction with respect to the first and second channel regions. Reference numeral 56 represents a region to which a gate voltage V_{G} may be applied to the contact region 48a.

Although not illustrated in FIG. 1, a gate insulating layer may be disposed in the first and second channel regions, a region between the first and second channel regions, and the fin part 48b. In such example embodiments, the gate insulating layer actually contacts the exposed surface of the first and second channel regions and the region between the first and second channel regions of the interlayer insulating layer 44. Likewise, although not illustrated in FIG. 1, gate spacers may be disposed in the fin part 48b of the gate 48, the first semiconductor layer 42, the interlayer insulating layer 44, and the second semiconductor layer 46. The gate spacers may prevent the fin part 48b of the gate 48 and the first and second semiconductor layers 42 and 46 from coming into contact. Also, the gate spacers may be used to form the first to fourth impurity regions 42a, 42b, 46a and 46b of the first and second semiconductor layers in a lightly doped drain (DLL) structure during the CMOS forming process.

In the structure shown, with the first and second semiconductor layers 42 and 46 and the fin part 48b of the gate 48, the fin part 48b of the gate 48 may control carriers passing through the first channel region of the first semiconductor layer 42 and carriers passing through the second channel region of the second semiconductor layer 46 according to a voltage applied to the contact region 48a of the gate 48.

Also, in the structure shown, with the first and second semiconductor layers 42 and 46 and the fin part 48b of the gate 48, the first semiconductor layer 42 and the fin part 48b of the gate 48 may be configured as an N-type fin FET, and the second semiconductor layer 46 and the fin part 48b of the gate 48 may be configured as a P-type fin FET.

First and second contact holes h1 and h2 may be formed in the second semiconductor layer 46. The first contact hole h1 and the second contact hole h2 may be formed in the fourth impurity region 46b and the third impurity region 46a, respectively. A power supply voltage (Vdd) applying region 54 may be disposed in the third impurity region 46a of the second semiconductor layer 46 together with the second contact hole h2. The second contact hole h2 may be spaced apart from the Vdd applying region 54.

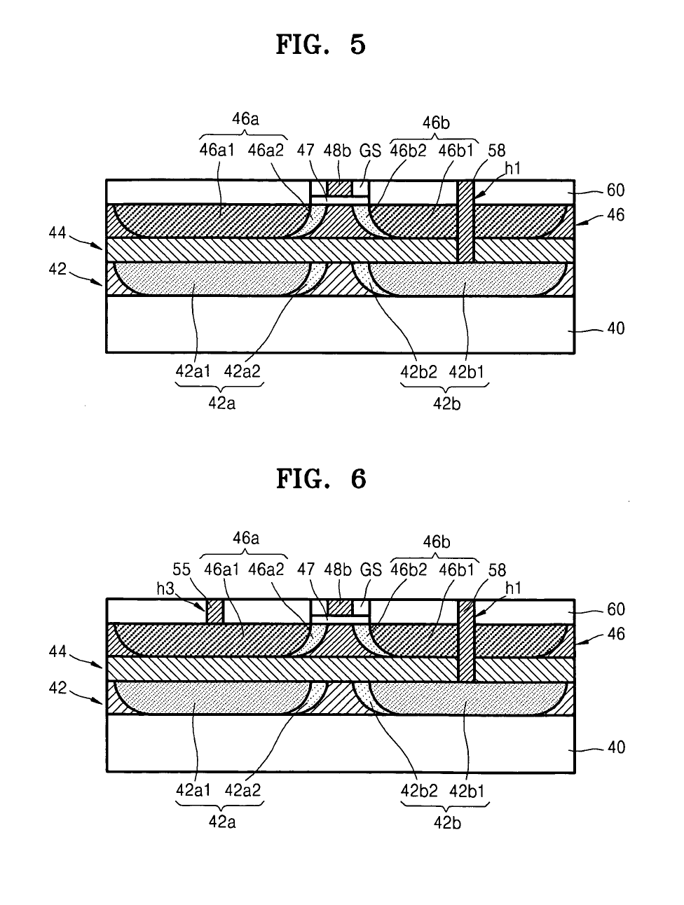

Although a second interlayer insulating layer covering the second semiconductor layer 46 is not illustrated in FIG. 1, for convenience, the second semiconductor layer 46 and the gate 48 may be covered with a second interlayer insulating layer in an actual manufacturing process. In an example embodiment, as illustrated in FIGS. 5 through 7, the V_{DD} applying region 54 and the region to which the gate voltage V_{G} is applied may be exposed through a contact hole formed in the second interlayer insulating layer. The contact hole may be filled with a conductive plug.

The first and second contact holes h1 and h2 formed in the second semiconductor layer 46 may pass through the interlayer insulating layer 44. The second impurity region 42b of the first semiconductor layer 42 may be exposed through the first contact hole h1, and the first impurity region 42a may be exposed through the second contact hole h2. The first contact hole h1 may be filled with a first conductive plug 58. An inner surface of the second contact hole h2, that is, the surface of the interlayer insulating layer 44 and the second semiconductor layer 46 exposed through the second contact hole h2, may be covered with a spacer 50. The spacer 50 may be a nitride layer. The second contact hole h2 inside the spacer 50 may be filled with a second conductive plug 52. The spacer 50 may prevent the second conductive plug 52 and the second semiconductor layer 46 from coming into contact with each other. An output voltage V_{Out} may be output through the first conductive plug 58. The second conductive plug 58 may be connected to ground.

In an example embodiment, a CMOS device according to example embodiments of the present invention may include an N-type transistor and a P-type transistor, which are sequentially stacked and have a fin type structure.

FIGS. 2 through 4 are plan views of a CMOS device according to an example embodiment of the present invention, in which cutting lines are drawn in different directions.

The plan views of FIGS. 2 through 4 are illustrated assuming that the second semiconductor layer 46 and the gate 48 are covered with a second interlayer insulating layer.

Referring to FIGS. 2 through 4, widths of the third and fourth impurity regions 46a and 46b of the second semiconductor layer 46 may be narrower nearer the second channel region of the second semiconductor layer 46 disposed under the fin part 48b of the gate 48. A distance Dl from the fin part 48b of the gate 48 to a position where the widths of the third and fourth impurity regions 46a and 46b begin to be narrower may be 50 nm or more.

Because the first semiconductor layer 42 has the same shape as the second semiconductor layer 46, the structural characteristic of the second semiconductor layer 46 may also be applied to the first semiconductor layer 42.

FIG. 5 is a sectional view taken along line 5-5′ in a direction crossing the first contact hole h1.

Referring to FIG. 5, the first and second impurity regions 42a and 42b of the first semiconductor layer 42 may have an LDD structure. The first impurity region 42a may include a first n+ doping region 42a1 and a first n− doping region 42a2. Most of the first impurity region 42a may be the first n+ doping region 42a1. The first n− doping region 42a2 may be disposed under the gate spacer GS. The second impurity region 42b may include a second n+ doping region 42b1 and a second n− doping region 42b2. Most of the second impurity region 42b may be the second n+ doping region 42b1. The second n− doping region 42b2 may be disposed under the gate spacer GS.

The third and fourth impurity regions 46a and 46b of the second semiconductor layer 46 may have an LDD structure. The third impurity region 46a may include a first p− doping region 46a1 and a first p− doping region 46a2. The first p− doping region 46a2 may be disposed under the gate spacer GS. Most of the third impurity region 46a may be the first p− doping region 46a1. The fourth impurity region 46b may include a second p− doping region 46b1 and a second p− doping region 46b2. Most of the fourth impurity region 46b may be the second p+doping region 46b1. The second p− doping region 46b2 may be disposed under the gate spacer GS.

In addition, a gate insulating layer 47 may be disposed on the first and second p− doping regions 46a2 and 46b2 and the second semiconductor layer 46 therebetween. The gate insulating layer 47 may be a silicon oxide layer (SiO₂). The fin part 48b of the gate 48 and the gate spacer GS covering the sides of the fin part 48b may disposed on the gate insulating layer 47. The second semiconductor layer 46 around the gate spacer GS may be covered with the second interlayer insulating layer 60. The second interlayer insulating layer 60 may be a silicon oxide layer.

It can be seen from FIG. 5 that the first contact hole h1 is formed in the stack structure including the second interlayer insulating layer 60, the fourth impurity region 46b, and the interlayer insulating layer 44. As described above, the second n+ doping region 42b2, that is, the second impurity region 42b of the first semiconductor layer 42, may be exposed through the first contact hole h1. The first contact hole h1 may be filled with the first conductive plug 58. Accordingly, the second impurity region 42b of the N-type fin transistor and the fourth impurity region 46b of the P-type fin transistor may be connected together through the first conductive plug 58.

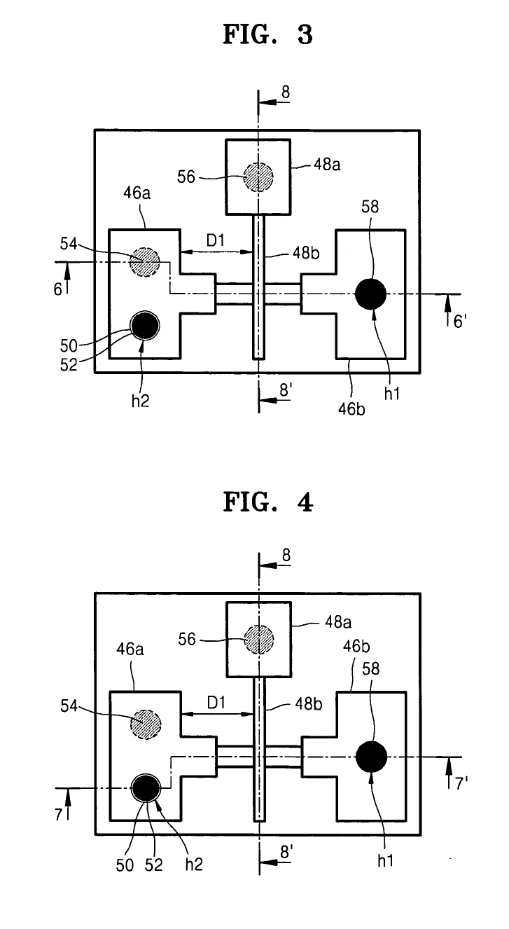

FIG. 6 is a sectional view taken along line 6-6′ of FIG. 3 in a direction crossing the first contact hole h1 and the VDD applying region 54.

Referring to FIG. 6, the third contact hole h3 is formed in the second interlayer insulating layer 60 covering the second semiconductor layer 46. The first p+ doping region 46a1 of the third impurity region 46a of the second semiconductor layer 46 may be exposed through the third contact hole h3.

Referring to FIGS. 3 and 6, it can be seen that the first p− doping region 46a1 exposed through the third contact hole h3 is the Vdd applying region 54a. The third contact hole h3 may be filled with the third conductive plug 55.

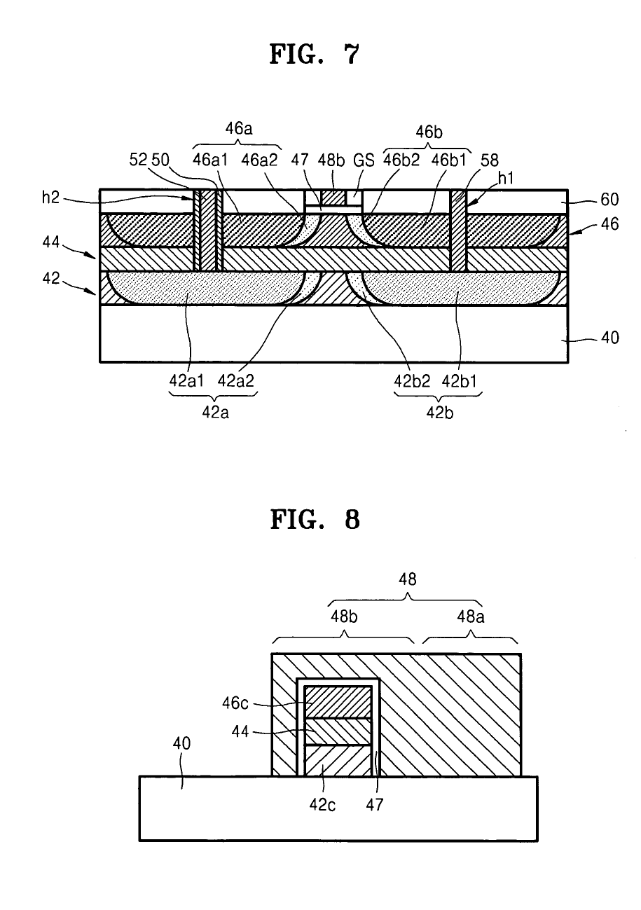

FIG. 7 is a sectional view taken along line 7-7 of FIG. 4 in a direction crossing the first and second contact holes h1 and h2.

Referring to FIG. 7, the second contact hole h2 exposing the first n+ doping region 42a1, that is, the first impurity region 42a of the first semiconductor layer 42, may be formed in the stack structure including the second interlayer insulating layer 60, the second semiconductor layer 46, and the interlayer insulating layer 44. Also, the inner side surface of the second contact hole h2 may be covered with the spacer 50. The second contact hole h2 inside the spacer 50 may be filled with the second conductive plug 52. The first semiconductor layer 42 may be grounded through the second conductive plug 52.

FIG. 8 is a sectional view taken along line 8-8′ in any one of FIGS. 4 through 8 in a direction traversing the gate 48.

Referring to FIGS. 2 and 8, reference numeral 42c represents the first channel region between the first and second impurity regions 42a and 42b of the first semiconductor layer 42, and a reference numeral 46c represents the second channel region between the third and fourth impurity regions 46a and 46b of the second semiconductor layer 46. As shown, the first channel region 42c, the interlayer insulating layer 44, and the second channel region 46c may be stacked in sequence. Side surfaces of the first channel region 42c and the side and top surfaces of the second channel region 46c may be covered with the gate insulating layer 47. The gate insulating layer 47 may be covered with the fin part 48b of the gate 48. The fin part 48b of the gate 48 may be formed vertically with respect to the first and second channel regions 42c and 46c.

A method of manufacturing the fin FET CMOS device according to an example embodiment of the present invention will now be described.

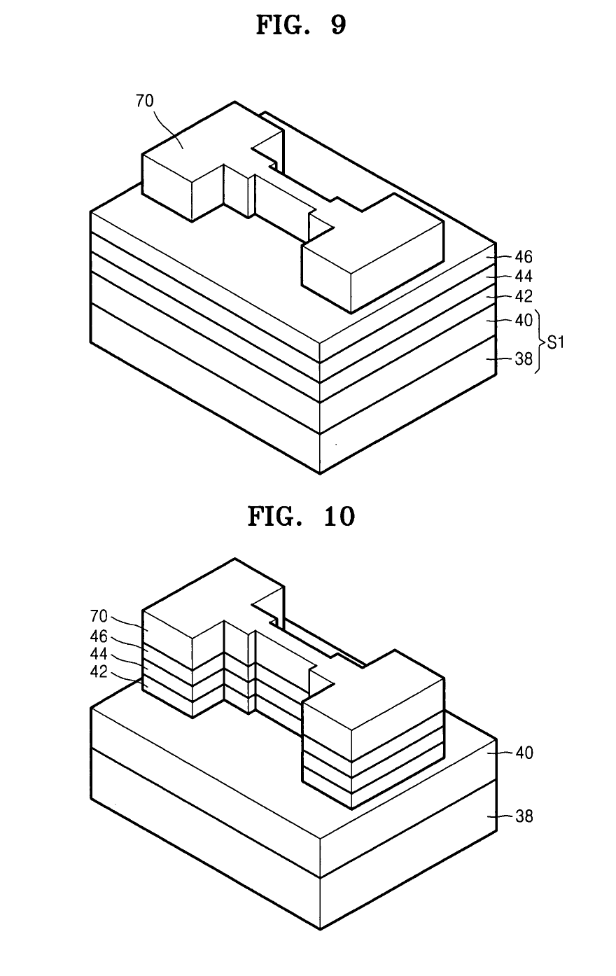

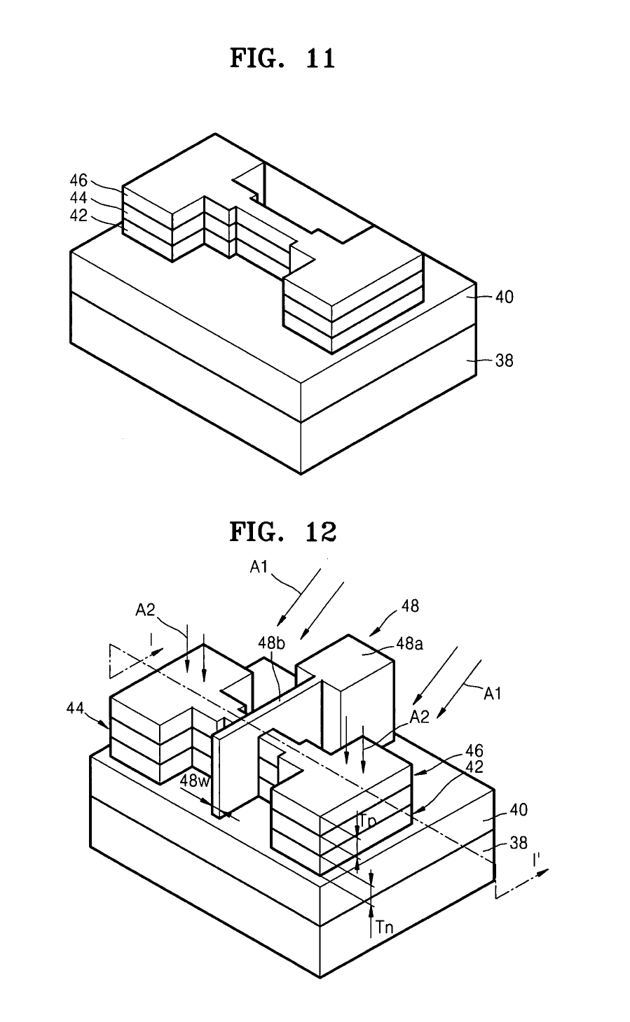

Referring to FIG. 9, an SOI substrate S1 may be provided which may include a silicon substrate 38 and a buffer layer 40 stacked on top of the silicon substrate 38. A first semiconductor layer 42, an interlayer insulating layer 44, and a second semiconductor layer 46 may be sequentially stacked on the buffer layer 40. The first semiconductor layer 42 may be formed of a silicon layer with a (100) crystal face. The second semiconductor layer 46 may be formed of a silicon layer with a (110) crystal face. Also, the interlayer insulating layer 44 may be formed of a silicon oxide layer. The first and second semiconductor layers 42 and 46 may be formed to about 50 nm thick, although thicknesses of the respective layers may vary. After forming the second semiconductor layer 46, a photoresist pattern 70 defining the second semiconductor layer 46 in a pattern of FIG. 1 may be formed on the second semiconductor layer 46. Using the photoresist pattern 70 as an etch mask, the second semiconductor layer 46, the interlayer insulating layer 44, and the first semiconductor layer 42 may sequentially etched. Etching may be performed until the buffer layer 40 is exposed. The resultant structure is illustrated in FIG. 10. After the etching, the photoresist pattern 70 is removed. The resultant structure after removing the photoresist pattern 70 is illustrated in FIG. 11.

Referring to FIG. 12, a fin gate 48 may be formed on the buffer layer 40 to cover a portion or an entire exposed surface of a portion to be used as the channel region in the first semiconductor layer 42 and the second semiconductor layer 46. The fin gate 48 may include a contact region 48a to which a gate voltage is applied and a fin part 48b, extended from the contact region 48a in a fin shape. The fin part 48b may be formed vertically in a portion to be used as the channel regions of the first and second semiconductor layers 42 and 46. The fin part 48b may be formed with a width 48w, for example, 30 nm. An entire exposed surface of the portion to be used as the channel regions in the first and second semiconductor layers 42 and 46 may be covered with the fin part 48b. The fin gate 48 may be formed using a lift-off method or a photolithography method. The fin gate 48 may be formed of metal.

A gate insulating layer (not shown) may be formed between the fin part 48band the first semiconductor layer 42, the second semiconductor layer 46 and the interlayer insulating layer 44. The gate insulating layer may be formed of material with high permittivity.

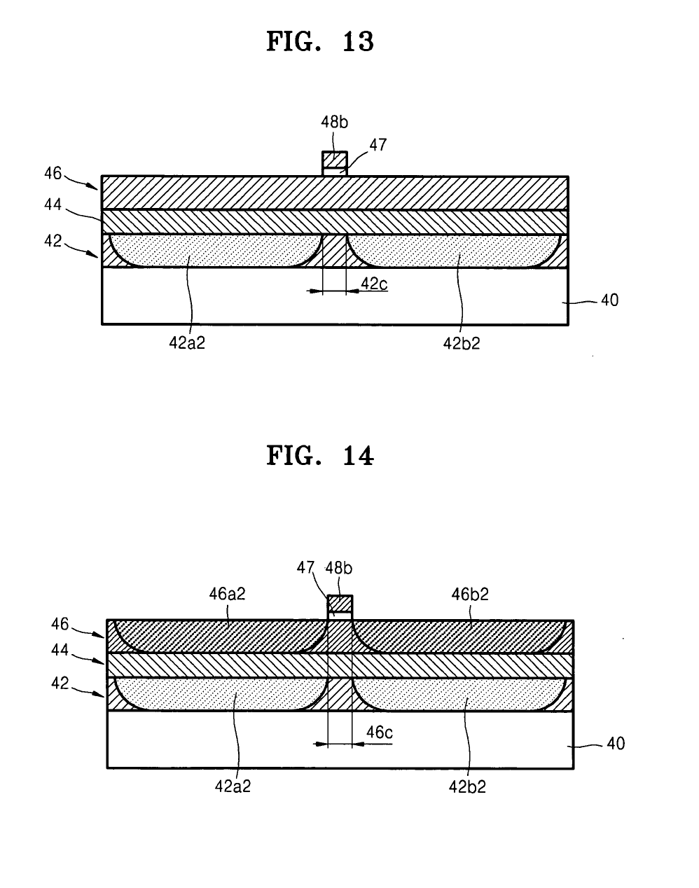

A method of manufacturing the CMOS device according to an example embodiment of the present invention will now be described with reference to FIG. 13. FIG. 13 is a sectional view taken along line I-I′ of FIG. 12.

Referring to FIG. 13, after forming the fin part 48b, a first n− doping region 42a2 and a second n− doping region 42b2 may be formed on the first semiconductor layer 42. The first and second n− doping regions 42a2 and 42b2 may be formed by doping n-type conductive impurities, for example, phosphorus (P) ions. The n-type conductive impurities may be obliquely doped at a desired angle with respect to the top surface of the second semiconductor layer 46 in a direction parallel to the fin part 48b. The desired angle may be 30°. In FIG. 12, a first arrow Al represents n-type conductive impurities that are obliquely doped. A region located under the fin part 48b of the first semiconductor layer 42 becomes the first channel region 42c.

Referring to FIG. 14, a first p− doping region 46a2 and a second p− doping region 46b2 may be formed in the second semiconductor layer 46. The first and second p− doping regions 46a2 and 46b2 may be formed by doping p-type conductive impurities, for example, boron (B) ions. In FIG. 12, a second arrow A2 represents p-type conductive impurities that are obliquely doped into the top surface of the second semiconductor layer 46. A region located under the fin part 48b of the second semiconductor layer 46 becomes the second channel region 46c.

In forming the doping regions, the doping concentration of the first and second p− doping regions 46a2 and 46b2 may be higher than that of the first and second n− doping regions 42a2 and 42b2 by, for example, one order of magnitude.

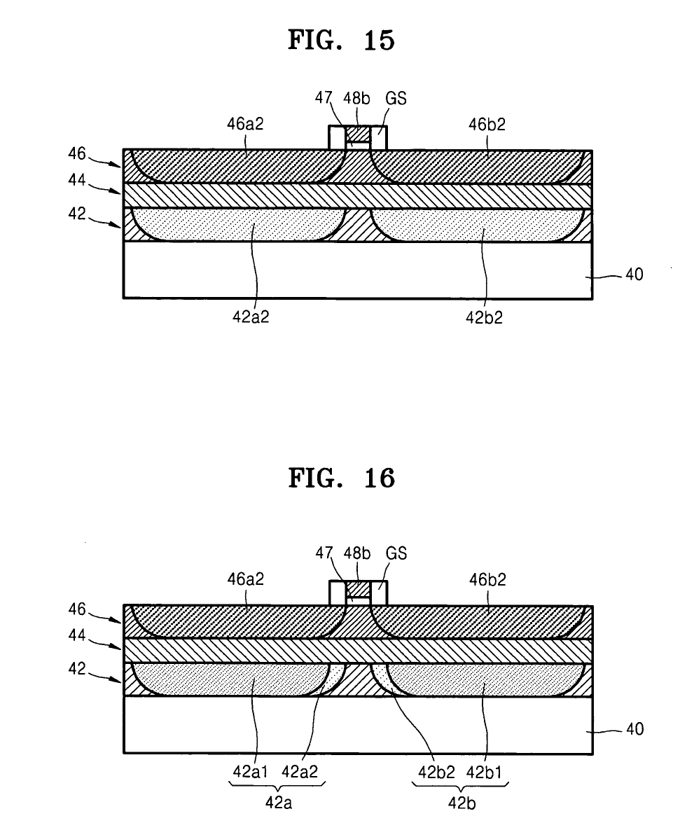

Referring to FIG. 15, a gate spacer GS may be formed on side surfaces of the fin part 48b. After forming an insulating layer to cover the fin part 48b, etching, for example, anisotropic dry etching, may performed on the insulating layer to form a gate spacer GS.

Referring to FIG. 16, after forming the gate spacer GS, a first n+ doping region 42a1 may be formed in the first n− doping region 42a2 using the fin part 48b and the gate spacer GS as a mask. Then, a second n+ doping region 42b1 is formed in the second n− doping region 42b2. Like the first and second n− doping regions 42a2 and 42b2, the first and second n+ doping regions 42a1 and 42b1 may be formed by obliquely doping n-type conductive impurities into the second semiconductor layer 46 at a desired angle with respect to the top surface of the second semiconductor layer 46. The desired angle may be 300. In the ion doping operation of forming first and second n+ doping regions 42a1 and 42b1, the n-type conductive impurities may be doped into all regions, except the region disposed under the gate spacer GS among the first and second n− doping regions 42a2 and 42b2. Accordingly, all regions except the region disposed under the gate spacer GS may become the first and second n+ doping regions 42a1 and 42b1. After the first and second n+ doping regions are formed, the first and second n− doping regions 42a2 and 42b2 may be restricted to a smaller, for example, narrower region disposed under the gate spacer GS. The doping concentration of the first and second n+ doping regions 42a1 and 42b1 may be higher than that of the first and second n− doping regions.

In this manner, the first and second impurity regions 42a and 42b, having an LDD structure, are formed in the first semiconductor layer 42. Also, the first channel region 42c may be formed between the first and second impurity regions 42a and 42b.

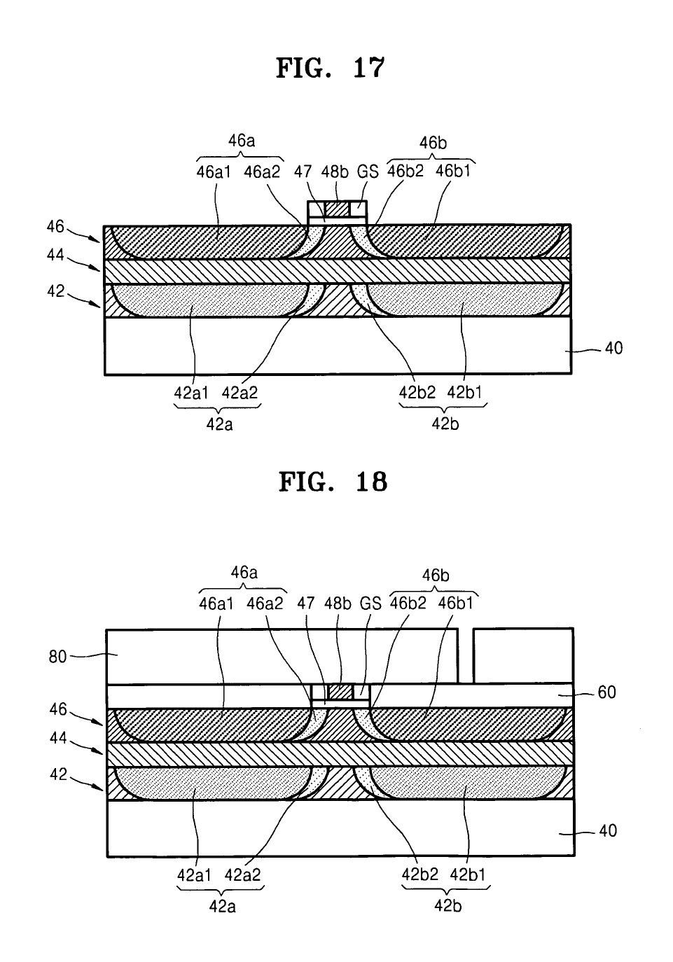

Referring to FIG. 17, after forming the first and second impurity regions 42a and 42b in the first semiconductor layer 42, first and second p− doping regions 46a2 and 46b2 may be formed in the second semiconductor layer 46. The doping concentration of the first and second p+ doping regions 46a2 and 46b2 may be higher than that of the first and second p− doping regions 46a1 and 46b1. Also, the doping concentration of the first and second p− doping regions 46a2 and 46b2 may be higher than that of the first and second n+ doping regions 42a1 and 42b1, for example, by one order of magnitude. In the ion doping operation of forming the first and second p− doping regions 46a1 and 46b1, the p-type conductive impurities may be doped into all regions of the first and second p− doping regions 46a2 and 46b2, except the region disposed under the gate spacer GS. Accordingly, after the ion doping operation of forming the first and second p− doping regions 46a1 and 46b1, most of the first and second p− doping regions 46a2 and 46b2 become the first and second p− doping regions 46a1 and 46b1, and the first and second p− doping regions 46a2 and 46b2 may be restricted to a smaller, for example, narrower region disposed under the gate spacer GS.

While forming the first and second p− doping regions 46a1 and 46b1, the third and fourth impurity regions 46a and 46b having an LDD structure may be naturally formed in the second semiconductor layer 46. A second channel region 46c covering the fin part 48b may be formed between the third and fourth impurity regions 46a and 46b. The third impurity region 46a may include the first p− doping region 46a2 and the first p− doping region 46a1, and the fourth impurity region 46bmay include the second p− doping region 46b2 and the second p− doping region 46b1.

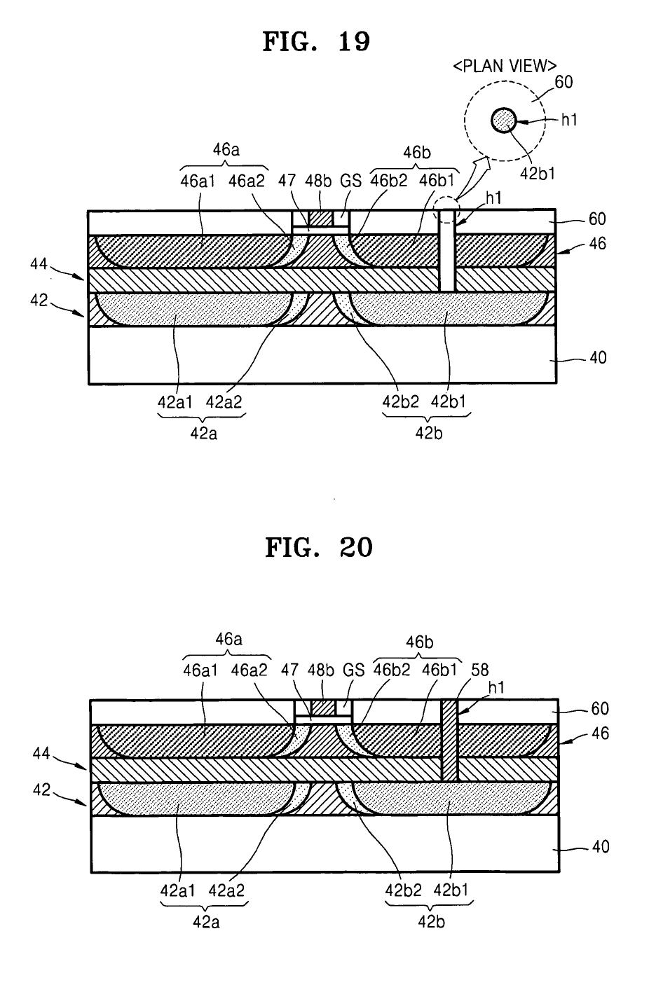

Referring to FIG. 18, a second interlayer insulating layer 60 may be formed to cover the second semiconductor layer 46 and the fin part 48b. The second interlayer insulating layer 60 may be formed of a silicon oxide layer. A photoresist pattern 80 defining a portion of the fourth impurity region 46b, that is, a portion of the second p− doping region 46b1, may be formed on the second interlayer insulating layer 60. Using the photoresist pattern 80 as an etch mask, the second interlayer insulating layer 60, the second semiconductor layer 46, and the interlay insulating layer 44 may be sequentially etched. The etching may be performed until the second n+ doping region 42b1 of the first semiconductor layer 42 is exposed. Then, the photoresist pattern 80 is removed. As a result of the etching, as illustrated in FIG. 19, a first contact hole h1 may be formed in the stack structure including the second interlayer insulating layer 60, the second semiconductor layer 46, and the interlayer insulating layer 44. The second impurity region 42b of the first semiconductor layer 42 may be exposed through the first contact hole h1.

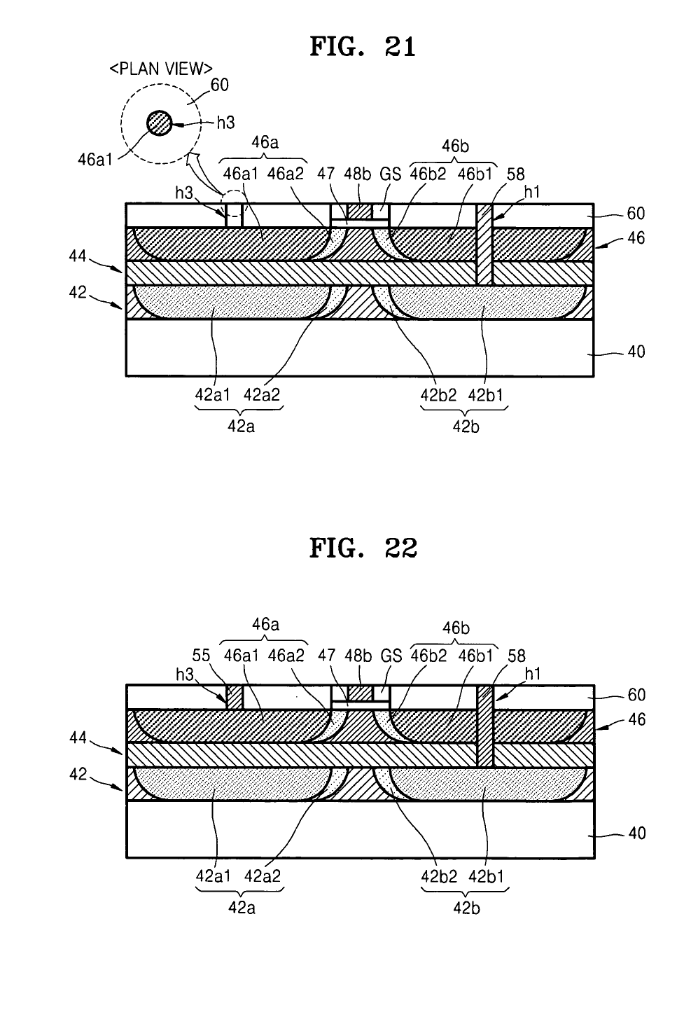

Referring to FIG. 20, the first contact hole h1 may be filled with a first conductive plug 58. Referring to FIG. 21, a third contact hole h3 may be formed in the second interlayer insulating layer 60 to expose the third impurity region 46a of the second semiconductor layer 46. The third contact hole h3 may be formed in the same way as that of the first contact hole h1. Referring to FIG. 22, the third contact hole h3 may be filled with the third conductive plug 55.

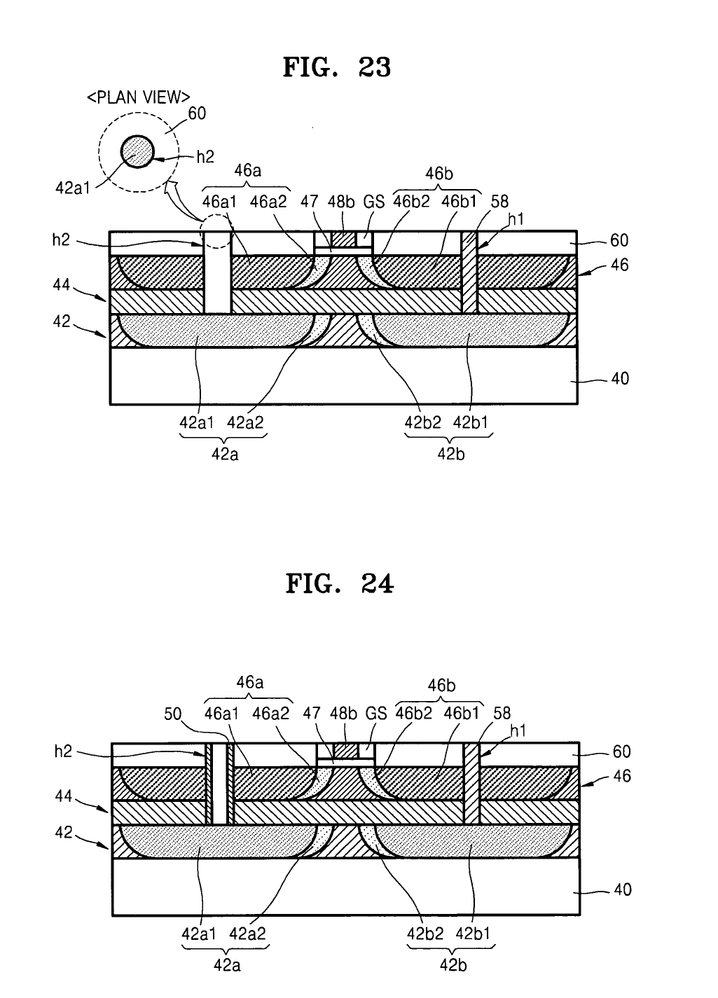

Referring to FIG. 23, a second contact hole h2 exposing the first p− doping region 42a1, that is, a portion of the first impurity region 42a, may be formed in the stack structure including the second interlayer insulating layer 60, the second semiconductor layer 46, and the interlayer insulating layer 44. The second contact hole h2 may be formed in the same way as that of the first contact hole h1.

As shown in FIGS. 2-4, because the plane of the second contact hole h2 is different from that of the third contact hole h3, the third contact hole h3 is not illustrated in the plane for explaining the second contact hole h2.

The filling of the second contact hole h2 will now be described.

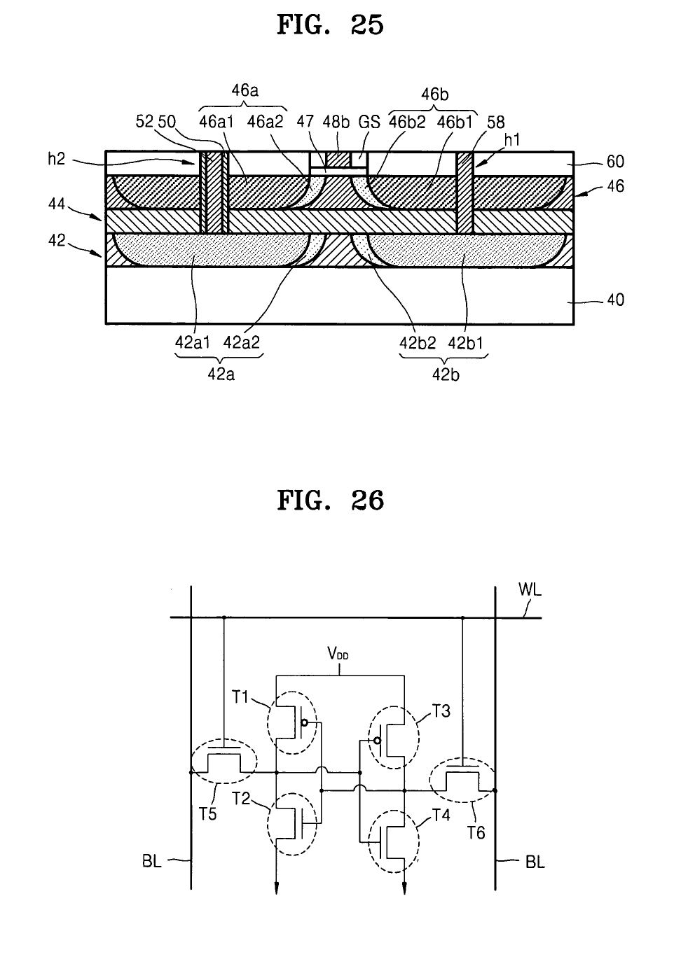

Referring to FIG. 24, the interlayer insulating layer 44, the second semiconductor layer 46, and the second interlayer insulating layer 60, which are exposed through the inner side surface of the second contact hole h2, may be covered with a spacer 50. The spacer 50 may be formed of an insulating layer, for example a nitride layer. Referring to FIG. 25, the remaining portion of the second contact hole h2, wherein the spacer 50 is formed may be filled with the second conductive plug 52. As a result of the spacer 50, the second conductive plug 52 is connected only to the first impurity region 42a of the first semiconductor layer 42.

The first to third contact holes h1 to h3 may be formed at the same time or in any order. However, considering that the depths of the first and second contact holes h1 and h2 are different from the depth of the third contact hole h3, the first and second contact holes h1 and h2 may be simultaneously formed and the third contact hole h3 may be separately formed. Because the depth of the first contact hole h1 is equal to that of the second contact hole h2, they can be simultaneously formed, but the operations of filling the first and second contact holes h1 and h2 may be different because materials filling the contact holes may be different.

A semiconductor memory device using the CMOS device according to an example embodiment of the present invention will now be described.

FIG. 26 is a circuit diagram of an SRAM using a CMOS device according to an example embodiment of the present invention.

In FIG. 26, a first transistor T1 may be a first p-type pull-up transistor and a second transistor T2 may be a first n-type pull-down transistor. A third transistor T3 may be a second p-type pull-up transistor and a fourth transistor T4 may be a second n-type pull-down transistor. Also, fifth and sixth transistors T5 and T6 may be first and second pass transistors, respectively. The fifth and sixth transistors T5 and T6 may both be n-type transistors. Reference symbols BL and WL represent a bit line and a word line, respectively.

In the SRAM of FIG. 26, the first and second transistors T1 and T2 and/or the third and fourth transistors T3 and T4 may be replaced with the CMOS device illustrated in FIG. 1. In an example embodiment, compared with the case where the first and second transistors T1 and T2 and/or the third and fourth transistors T3 and T4 are horizontally spaced apart on the substrate, the area occupied by the first and second transistors T1 and T2 and/or the third and fourth transistors T3 and T4 in the SRAM may be reduced. This results in the increase in the integration of the SRAM.

According to example embodiments of the present invention, after the second semiconductor layer 46 is doped, the first semiconductor layer 42 may be doped. Also, the positions of the P-type transistor and the N-type transistor may be exchanged. Further, one or more other fin FET CMOS devices may be stacked on the fin FET CMOS device of FIG. 1.

As described above, a CMOS device according to example embodiment of the present invention may be formed by sequentially stacking the N-type transistor and the P-type transistor, each having a fin structure. While maintaining the advantages of the CMOS device, the area where the CMOS device is formed may be smaller than the conventional CMOS device. Therefore, a CMOS device with a sufficient degree of integration may be obtained. Also, the memory (e.g., SRAM or other random access memory or other memory) including such a CMOS device may reduce power consumption, operate at higher speed, and/or have an increased integration degree.

While the present invention has been particularly shown and described with reference to example embodiments thereof, it will be understood by those of ordinary skill in the art that various changes in form and details may be made therein without departing from the spirit and scope of the present invention as defined by the following claims.

What is claimed is:

1. A CMOS device comprising:
a substrate;
an n-type transistor disposed on the substrate;
an interlayer insulating layer disposed on the n-type transistor; and
a p-type transistor disposed on the interlayer insulating layer,
wherein the n-type transistor and the p-type transistor have a common gate insulating layer and a common fin gate.

2. The CMOS device of claim 1, wherein a source of the n-type transistor and a drain of the p-type transistor are connected to a conductive plug, the source of the n-type transistor being grounded.

3. The CMOS device of claim 2, wherein a contact hole exposing the source of the n-type transistor is formed in a stack structure including the interlayer insulating layer and a source of the p-type transistor, an inner side surface of the contact hole is covered with a spacer, and the contact hole inside the spacer is filled with a conductive plug.

4. The CMOS device of claim 1, wherein the source and the drain of the n-type and p-type transistors have an LDD (lightly doped drain) structure.

5. The CMOS device of claim 4, wherein a doping concentration of the source and the drain of the p-type transistor is higher than a doping concentration of the source and the drain of the n-type transistor by at least one order of magnitude.

6. The CMOS device of claim 3, wherein the spacer is formed of a nitride layer.

7. The CMOS device of claim 1, wherein the n-type transistor is formed on a first semiconductor layer with a (100) crystal face.

8. The CMOS device of claim 1, wherein the p-type transistor is formed on a second semiconductor layer with a (110) crystal face.

9. The CMOS device of claim 1, wherein the interlayer insulating layer is about 50 nm thick.

10. The CMOS device of claim 7, wherein the first semiconductor layer is a silicon layer and is 50 nm thick.

11. The CMOS device of claim 8, wherein the second semiconductor layer is a silicon layer and is 50 nm thick.

12. The CMOS device of claim 1, wherein the gate insulating layer is about 30 nm wide.

13. The CMOS device of claim 1, wherein the substrate is an SOI (silicon on insulator) substrate.

14. A method of manufacturing a CMOS device, comprising:
sequentially stacking a first semiconductor layer, an interlayer insulating layer, and a second semiconductor layer;
forming a mask on a portion of the second semiconductor layer;
sequentially etching an exposed portion of the second semiconductor layer, and the interlayer insulating layer and the first semiconductor layer disposed under the exposed portion;
removing the mask;
sequentially forming a gate insulating layer and a gate with a fin part, the gate insulating layer entirely covering the exposed portion of the second semiconductor layer, the interlayer insulating layer, and the first semiconductor layer;
forming first and second n− doping regions on the first semiconductor layer and spaced apart from each other by the fin part;
forming first and second p− doping regions on the second semiconductor layer and spaced apart from each other by the fin part;
forming a gate spacer on a side surface of the fin part;
forming first and second n+ doping regions in the first and second n− doping regions using the gate spacer as a mask; and
forming first and second p− doping regions in the first and second p− doping regions using the gate spacer as a mask.

15. The method of claim 14, wherein the first semiconductor layer is formed of a silicon layer with a (100) crystal face.

16. The method of claim 14, wherein the second semiconductor layer is formed of a silicon layer with a (110) crystal face.

17. The method of claim 15, wherein the first semiconductor layer is about 50 nm thick.

18. The method of claim 16, wherein the second semiconductor layer is about 50 nm thick.

19. The method of claim 14, wherein the fin part of the gate is about 30 nm wide.

20. The method of claim 14, wherein the fin gate is formed using a lift-off method.

21. The method of claim 14, wherein the first and second n− doping regions are formed by obliquely doping n-type conductive impurity ions at an angle.

22. The method of claim 14, wherein the first and second n+ doping regions are formed by obliquely doping n-type conductive impurity ions at an angle.

23. The method of claim 21, wherein the angle is about 30°.

24. The method of claim 14, wherein a doping concentration of the first and second p− doping regions higher than that of the first and second n− doping regions by at least one order of magnitude.

25. The method of claim 14, wherein a doping concentration of the first and second p− doping regions is higher than that of the first and second n+ doping regions by at least one order of magnitude.

26. The method of claim 14, further comprising:
forming a second interlayer insulating layer on the substrate to cover the second semiconductor layer, the interlayer insulating layer, the first semiconductor layer, the fin gate, and the gate spacer;
forming a contact hole exposing the second n+ doping region in a stack structure, the stack structure including the second interlayer insulating layer, the second semiconductor layer, and the interlayer insulating layer;
filling the contact hole with a conductive plug;
forming a contact hole exposing the first p− doping region and a contact hole exposing the gate in the second interlayer insulating layer;
filling the contact hole exposing the first p− doping region and the gate with a conductive plug;
forming a contact hole exposing the first n+ doping region in a stack structure, the stack structure including the second interlayer insulating layer, the second semiconductor layer, and the interlayer insulating layer;
forming a spacer to cover an inner surface of the contact hole exposing the first n+ doping region; and
filling the contact hole inside the spacer with a conductive plug.

27. The method of claim 26, wherein the spacer is formed of a nitride layer.

28. The method of claim 14, further comprising:
forming a second interlayer insulating layer on the substrate to cover the second semiconductor layer, the interlayer insulating layer, the first semiconductor layer, the fin gate, and the gate spacer;
forming a first contact hole exposing the second n+ doping region and a second contact hole exposing the first n+ doping region in a stack structure, the stack structure including the second interlayer insulating layer, the second semiconductor layer, and the interlayer insulating layer;
filling the first contact hole with a conductive plug in a state in which the second contact hole is masked;
forming a spacer to cover an inner surface of the second contact hole in a state in which the second contact hole is unmasked;
filling the second contact hole inside the spacer with a conductive plug;
forming a contact hole exposing the first p− doping region and a contact hole exposing the gate in the second interlayer insulating layer; and
filling the contact hole exposing the first p− doping region and the contact hole exposing the gate with a conductive plug.

29. The method of claim 28, wherein the spacer is formed of a nitride layer.

30. The method of claim 22, wherein the angle is about 300.

31. A memory device comprising:
the CMOS device of claim 1, wherein the p-type transistor is a pull-up transistor and the n-type transistor is a pull-down transistor, with the interlayer insulating layer interposed therebetween.

32. The memory device of claim 31, wherein the memory device is an SRAM.

33. The memory device of claim 32, wherein the n-type pull-down transistor is formed of a silicon layer with a (100) crystal face.

34. The memory device of claim 32, wherein the p-type pull-up transistor is formed of a silicon layer with a (110) crystal face.

35. The memory device of claim 32, wherein a doping concentration of source and drain of the p-type pull-up transistor is higher than a doping concentration of source and drain of the n-type pull-down transistor by at least one order of magnitude.

36. The memory device of claim 32, wherein a drain region of the p-type pull-up transistor and a drain region of the n-type pull-down transistor are connected together through a conductive plug.

37. The memory device of claim 32, wherein a contact hole exposing the source of the n-type pull-down transistor is formed in a stack structure including a source region of the p-type pull-up transistor and the interlayer insulating layer, an inner surface of the contact hole is covered with a spacer, and the contact hole inside the spacer is filled with a conductive plug.

38. The memory device of claim 37, wherein the spacer is formed of a nitride layer.

39. The memory device of claim 32, wherein a second interlayer insulating layer is disposed on the p-type pull-up transistor, a contact hole exposing a source region of the p-type pull-up transistor and a contact exposing the fin gate are formed in the second interlayer insulating layer, the contact holes are filled with a conductive plug.
